(19) United States
(12) Patent Application Publication
(10) Pub. No.: US 2026/0219299 A1
(43) Pub. Date: Jul. 30, 2026

(54) FAST INSPECTION OF DEVICE UNDER TEST

(71) Applicant: InZiv Ltd., Jerusalem (IL)

(72) Inventors: David Judah LEWIS, Jerusalem (IL); Eran MAAYAN, Jerusalem (IL); Ori DADOOSH, Jerusalem (IL); Andrey IGNATOV, Jerusalem (IL); Alexander KROL, Jerusalem (IL); Baoting HUANG, Jerusalem (IL); Alexander GRESERMAN, Jerusalem (IL); Eyal COHEN, Jerusalem (IL); Yuval YOHAI, Jerusalem (IL); Rina DEKHTER, Jerusalem (IL)

(73) Assignee: InZiv Ltd., Jerusalem (IL)

(21) Appl. No.: 19/157,955

(22) PCT Filed: Jan. 3, 2024
(86) PCT No.: PCT/IB2024/050055

§ 371 Date: Aug. 19, 2025

Related U.S. Application Data
(60) Provisional application No. 63/511,176, filed on Jun. 29, 2023.

(51) Int. Cl. G01R 1/073; G01R 31/26

(52) U.S. Cl. CPC G01R 1/07364; G01R 1/07342; G01R 1/07357; G01R 31/2635

(57) ABSTRACT

An example method to test a collection of individual devices of a device under test (DUT) uses a test tool having probes and includes sequentially testing multiple pluralities of individual devices while the probes remain in physical contact with the DUT by moving the probes and/or the DUT while maintaining physical contact between the probes and the DUT, where the moving brings, for each successive plurality, the probes (i) into parallel electrical contact with a set of contacts associated with the plurality to drive their parallel electrical excitation, then (ii) out of electrical contact with the set of contacts. Another example method electrically couples a power source to probes positioned at a first side of a DUT and a conductive surface positioned at a second side of the DUT, then controllably electrically excites a plurality of individual devices by applying an alternating voltage to the probes relative to the conductive surface.

### BACKGROUND

Devices such as electronic, optoelectronic, electromechanical and other types of devices can be inspected and tested. An example testing modality is electrical excitation of a device, which imposes a voltage or current to a contact that is in electrical communication with the device. Typically, in this example, the device and the contact are part of the same circuit, and the imposition of the current/voltage is to drive excitation of the device to produce a variety of signals, such as emission values. These may then be monitored or sensed optically and/or electrically and recorded for analysis. A device subjected to such testing may be referred to as a device under test (DUT).

### SUMMARY

Shortcomings of the prior art are overcome and additional advantages are provided through the provision of a method for testing a collection of individual devices of a device under test (DUT). The method uses a test tool that includes a plurality of probes, and the method includes sequentially testing multiple pluralities of individual devices, of the collection of individual devices, while the plurality of probes remains in physical contact with the DUT. The sequentially testing includes moving at least one of the plurality of probes or the DUT while maintaining physical contact between the plurality of probes and the DUT, where the moving brings, for each successive plurality of the multiple pluralities of individual devices, the plurality of probes (i) into parallel electrical contact with a set of contacts associated with the plurality of individual devices to drive parallel electrical excitation of the plurality of individual devices, then (ii) out of electrical contact with the set of contacts associated with the plurality of individual devices. The method additionally includes detecting signals emitted from each plurality of individual devices of the multiple pluralities of individual devices based on the electrical excitation thereof.

In some embodiments, the individual devices are micro light-emitting diode (microLED) devices.

In some embodiments, the moving moves the plurality of probes across the DUT with a continuous movement and consistent speed.

In some embodiments, each probe of the plurality of probes includes a flexible probe end that flexes on physical contact with the DUT. The moving can move the plurality of probes over a surface of the DUT having variation in flatness corresponding to the collection of individual devices, and the plurality of probes can flex and maintain physical contact with the DUT while moving over the collection of individual devices.

In some embodiments, the driving imposes a voltage or current, via the plurality of probes, to the set of contacts into which the plurality of probes is in contact to drive the parallel electrical excitation of the plurality of individual devices associated with the set of contacts. In some embodiments, each probe of the plurality probes includes a respective individual electrical channel to selectively excite a respective individual device of the plurality individual devices. A first individual electrical channel of a first probe of the plurality of probes could therefore provide a voltage or current level that is different from a voltage or current level provided by a second individual electrical channel of a second probe of the plurality of probes.

In some embodiments, a probe of the plurality of probes is a conductive plane that, for each plurality of individual devices of the multiple pluralities of individual devices, comes into simultaneous electrical contact with two or more contacts of the set of contacts associated with the plurality of individual devices, and drives parallel electrical excitation of two or more individual devices of the plurality of individual devices associated with the two or more contacts.

In some embodiments, the method further includes synchronizing, with the moving, a trigger to a detection system performing the detecting, the synchronizing selectively and sequentially enabling and disabling detection of the signals to coincide with sequential excitation of the multiple pluralities of individual devices.

In another aspect, a method is provided for testing a collection of individual devices of a DUT and uses a test tool that includes a plurality of probes, and the method includes electrically coupling a power source to (i) the plurality of probes positioned at a first side of the DUT and (ii) a conductive surface positioned at a second side of the DUT, controllably electrically exciting a plurality of individual devices, of the collection of individual devices, by applying an alternating voltage to the plurality of probes relative to the conductive surface, where non-conductive material is disposed between (i) at least one of the conductive surface or the plurality of probes and (ii) respective electrical contacts associated with the plurality of individual devices, and detecting signals emitted from the plurality of individual devices based on the electrical excitation thereof.

In some embodiments, the plurality of individual devices is a first plurality of the individual devices of the collection of individual devices and the plurality of probes electrically excite the first plurality of individual devices, and the method further includes moving at least one of the plurality of probes or the DUT, wherein the moving electrically excites a next plurality of individual devices of the collection of individual devices, detecting signals emitted from the next plurality of individual devices based on the electrical excitation thereof, and repeating, one or more times, the moving and the detecting for a respective one or more additional plurality of individual devices. In embodiments, the plurality of individual devices is a first plurality of the individual devices of the collection of individual devices, the plurality of probes is in physical contact with the DUT, and the method further includes moving at least one of the plurality of probes or the DUT while maintaining the physical contact between the plurality of probes and the DUT, wherein the moving electrically excites a next plurality of individual devices of the collection of individual devices, detecting signals emitted from the next plurality of individual devices based on the electrical excitation thereof, and repeating, one or more times, the moving and the detecting for each of one or more additional plurality of individual devices.

In some embodiments, the conductive surface is transparent and the detecting is performed from the second side of the DUT based on the signals passing through the transparent conductive surface.

In some embodiments, the DUT includes a non-conductive layer over the individual devices, and the plurality of probes include flexible probe ends that flex on physical contact with the non-conductive layer of the DUT.

Additional aspects of the present disclosure are directed to systems and computer program products configured to perform the methods described above and herein. The present summary is not intended to illustrate each aspect of, every implementation of, and/or every embodiment of the present disclosure. Additional features and advantages are realized through the concepts described herein.

### BRIEF DESCRIPTION OF THE DRAWINGS

Aspects described herein are particularly pointed out and distinctly claimed as examples in the claims at the conclusion of the specification. The foregoing and other objects, features, and advantages of the disclosure are apparent from the following detailed description taken in conjunction with the accompanying drawings in which:

FIG. 1A depicts an example of contact-based testing with a flexible probe;

FIG. 1B depicts an example probe configuration having a plurality of probes for multiple-DUT electrical contact, in accordance with aspects described herein;

FIG. 1C depicts an example probe configuration of a plurality of probes with individual channels for excitation, in accordance with aspects described herein;

FIG. 2 depicts FIG. 2 depicts another example probe configuration in accordance with aspects described herein;

FIGS. 3 and 4 depict example probe configurations utilizing conductive plane(s) for testing devices, in accordance with aspects described herein;

FIGS. 5 and 6 depict examples of capacitive-based electrical excitation in accordance with aspects described herein;

FIG. 7 depicts an example of an optoelectronic device under test in which emitted signals are detected from a bottom of the device, in accordance with aspects described herein;

FIG. 8 depicts an example of an optoelectronic device under test in which emitted signals are detected from atop the device, in accordance with aspects described herein;

FIG. 9 depicts an example probe support housing with probe retention using a spring structure, in accordance with aspects described herein;

FIGS. 10 and 11 depict example methods for testing a collection of individual devices of a device under test (DUT); and

FIG. 12 depicts one example of a computer system and associated devices to incorporate and/or use aspects described herein.

### DETAILED DESCRIPTION

Described herein are facilities, e.g., tools and methods, for excitation and testing of devices, for instance those provided on a surface/substrate. More generally, aspects can be used for testing not just devices but other types of samples, and therefore references to “device” or “devices” herein should not be taken as being limited in this regard to just device types of samples. In some aspects, the induced excitation of the DUT can be imposed repeatedly with minimal or no degradation in terms of the efficacy of the tool or the DUT.

Geometries that meet desired use cases of the tool can enable transparent optical or other forms of readout that result from this excitation to facilitate evaluation of DUT performance.

One of several examples of such testing is electro-optical electroluminescence for micro light-emitting diode (LED) (also referred to as “microLED” “micro-LED”, “mLED”, and “μLED”) display inspection. Many examples described herein are presented with reference to testing of microLEDs. MicroLED testing can be particularly useful for microLED display inspection. MicroLED displays incorporate millions of microLEDs, and efficient testing thereof is a crucial step in achieving large-scale manufacture and marketability of microLED displays.

Aspects described herein enable simultaneous testing using arrays of probes. Simultaneous (alternatively referred to as ‘parallel’) testing in accordance with aspects described herein can achieve excellent, consistent, and repeatable results. Examples involve electrical interactions in parallel (i.e., simultaneously to a plurality of devices) to effectively excite arrays of the devices for inspection. Though features described herein are presented with specific reference to microLEDs, those with ordinary skill in the art will appreciate that features described herein can be used in testing/inspection of a variety of devices and types of samples, including electro-mechanical, electro-optical, and other types of devices/samples, and further that aspects can apply to both single element testing and multiple element testing, e.g., arrays of devices.

In some embodiments, a tool is provided that operates as a series of probes to impose voltage or current to contact points in order to excite a plurality of corresponding devices (e.g. electronic, optoelectronic, or electromechanical DUT, as examples), and then optically and/or electrically measure and monitor the signals produced from the plurality of devices being excited. The probes make electrical contact at multiple sites in-parallel, meaning simultaneously.

In contact-based testing, test probes are placed in physical contact with the contact points and with some appreciable level of force applied. The probes could be made with the appropriate flexibility, in essence ‘soft-touch’/flexible, such that they can be applied with or without a need for monitoring and adjustment (as active feedback)to adjust their flex or bending, e.g., akin to how a brush end of a paint brush would flex/bend when the brush is applied with some force to a surface. The flexibility of the probes allows for rapid testing of a plurality of devices under test (DUTs). For instance, in some embodiments, there may be a relative movement between the probe array and the DUTs, for instance movement in the horizontal direction relative to the DUT surface without damaging the probes and the DUT. This enables fast testing of a large number of DUTs.

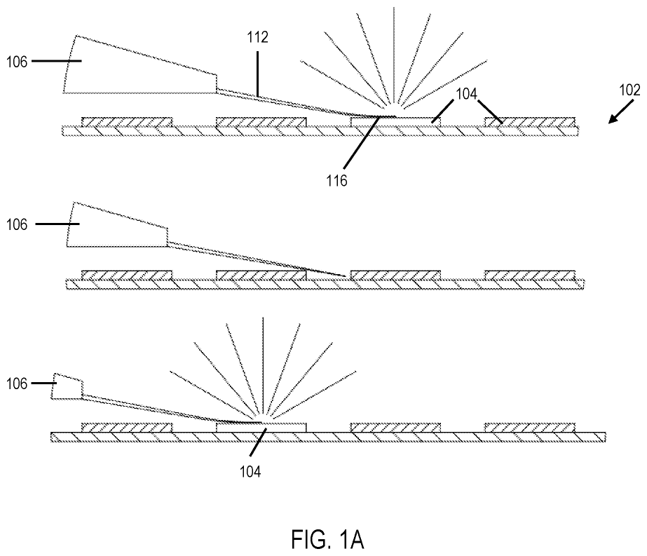

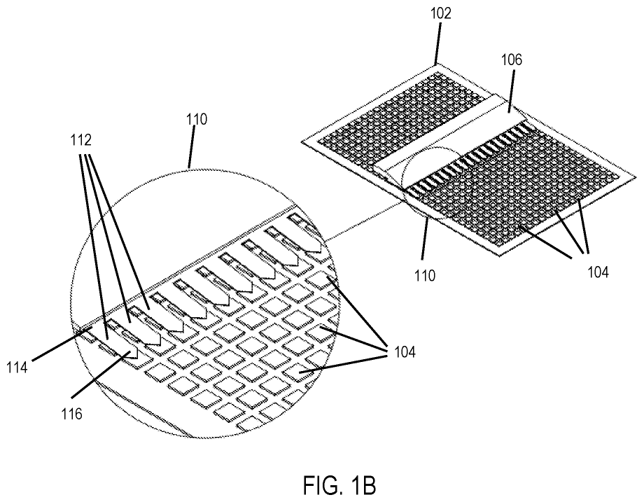

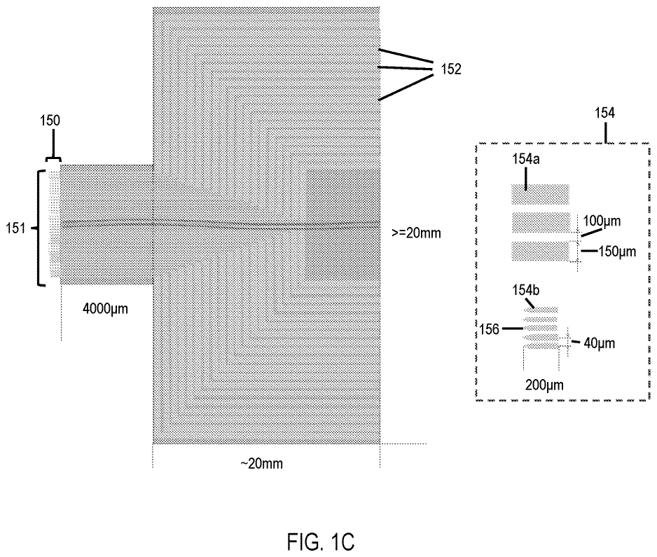

FIG. 1A depicts an example of contact-based testing with a flexible probe. One probe 112 is shown in FIG. 1A. The probe 112 is used to test DUT 102 that includes a plurality of individual devices 104 (which may individually be referred to as devices under test or DUT), for instance microLEDs. At least a portion of the probe 112 of FIG. 1A is flexible, for instance probe 112 has a flexible end 116. Electrical contact is made between individual DUTs 104 and the probe 112, specifically the flexible end 116 thereof, and may be made in sequence to drive excitation of the individual DUTs 104, for instance by way of relative movement between the probe 112 and the individual DUTs 104 in the horizontal direction, for instance movement of the probe 112 relative to a surface of the DUT 102, for instance as part of a scanning of the DUT by/using the probe.

Methods and devices discussed herein enable repeated simultaneous, flexible, electrical contact and interactions to excite, with functional efficacy, multiple devices under test, without damage to the probe or devices, and without requiring and/or undertaking any measure/monitor of active feedback (but permitting such active feedback if so desired). In some examples, this is provided via appropriate mechanical characteristics such that a plurality of probes can repeatedly make appropriate interaction with electrical contacts of device(s) without damaging the probe or device structure. The flexibility of the probes may be selected and imparted to be suitable for relatively large lateral devices with variations in flatness. The physical/electrical contact between the probes and the DUT can thus be maintained throughout the test of a plurality of devices (via electrical contact pads of/associated with those devices), even though there may be a variation in flatness across the DUT. The flexibility also enables a longer life probe, as the flexibility limits or eliminates damage to the probe.

Probe configuration can vary depending on the particular DUT. When considering probe configurations of a plurality of probes (such as an array of probes (“probe array”), which in some examples are arranged in a line of probes), a flexible probe array may be fabricated with an appropriate pitch and geometry to provide, if desired, an unobstructed view of the DUT at the highest powers of optical microscopy when exciting the DUT.

Silicon-based and other microfabrication technologies such as 3D printing can provide what is needed in terms of fabricating the probe array with proper flexibility, mechanical characteristics, geometry, and electrical patterning for supplying the necessary electrical input and output as dictated by the particular parameters of the DUT to achieve desired excitation.

FIG. 1B depicts an example probe configuration having a plurality of probes for multiple-DUT electrical contact, in accordance with aspects described herein. The probe configuration of FIG. 1B is used to test a device under test 102 that includes a plurality of individual devices 104, for instance microLEDs. The plurality of individual devices 104 are patterned/arranged in an array in this example. Probe support structure/housing 106 (also depicted in FIG. 1A), which supports/houses a plurality of individual probes 112, is provided as part of a test device/tool. Portion 110 shows further details of a subset of the array of probes, which generally each extend as an arm from the support structure/housing 106.

A probe 112 has a base portion 114 and an end portion 116. Here, the end portion 116 forms a tip (a pyramid, triangle, or cone, or ball, as examples). In some embodiments, the tip extends underneath the rest of the probe and makes electrical contact with the sample. In other embodiments, each probe is provided without a tip (i.e., pyramid, triangle, cone, or ball, etc.) and instead has a flat/straight surface that comes to contact with the sample. A probe of the latter design (e.g., without a tip) can sometimes provide an advantage in that testing can be accomplished with less pressure being imposed from the probe tip onto the DUT. This, in turn, can minimize or eliminate damage to the DUT, extend the life of the probe, and enable faster scan speeds (‘scan’ referring, in the context of this disclosure, to the action of sweeping the probes over the individual devices of the DUT with physical (in come embodiments) contact being maintained between the probes and the DUT while the individual devices are tested in consecutive batches of simultaneously-excited individual devices.

Each individual probe of a probe array could have a respective individual voltage/current channel that enables the selective excitation (or non-excitation) of different DUTs independently and optionally with different/unique values of voltage/current, if desired (i.e., each channel could provide a same or different voltage/current as that provided any other individual channel). Each individual probe could provide respective measurements of different DUTs independently via the individual channel of the probe.

FIG. 1C depicts an example probe configuration of a plurality of probes 151 with individual channels (152; only some of which are labeled in FIG. 1C). Cantilever length is denoted by 150. Example probe shapes are shown by 154 (flat/straight-ended probes 154a with a probe width of 150 μm (micron) and spacing of 100 μm, or tip-ended probes 154b with spacing of 40 μm between ends of the tips 156). Cantilever length in this example is 200 μm. These are provided as non-limiting examples, as probe dimensions, spacing, etc., could vary as desired, for instance according to the particular characteristics of the DUT.

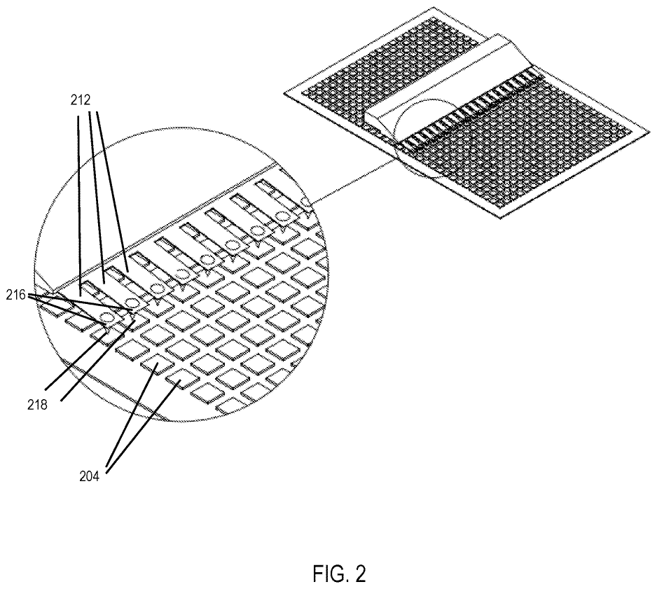

FIG. 2 depicts another example probe configuration with tips for contacting a plurality of DUT electrical contacts. The configuration is substantially similar to that of FIG. 1B except that end portions 216 of probes 212 have tips 218 that extend (downward in this example) from the underside of the probes 212 toward the individual devices 204.

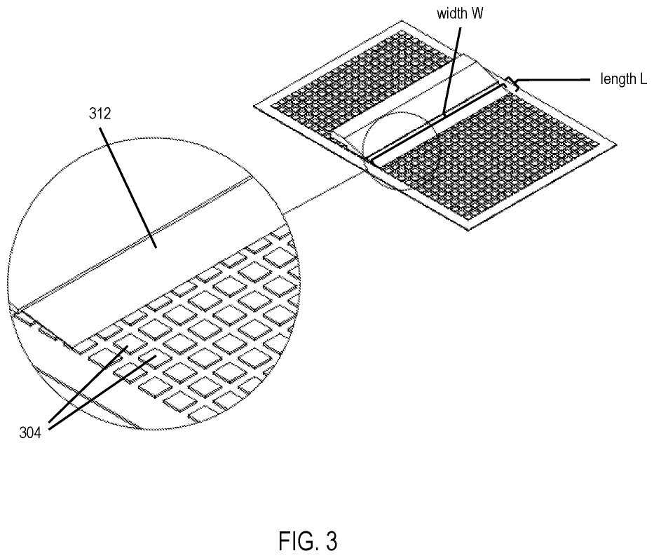

Another embodiment of a probe structure includes, instead of an individual line of probes each for engaging with a single individual device at a time, a conductive plane that, as an example, could be of a same length as the individual probes of FIGS. 1A, 1B, 1C and/or 2, but of a width W that is, for instance, of a same width as a whole line of probes depicted in FIGS. 1A, 1B, 2. Such a structure with a conductive plane 312 for testing devices 304 is depicted in FIG. 3. Dimensions (W, length L) of the conductive plane could change and vary according to the particular DUT. An advantage of a probe as in the configuration of FIG. 3 is the ability to excite a larger number of LED structures (or other devices/samples) without the need to change a probe card design as well as wafer design, where the sample (e.g., LED) pitch or/and width could be smaller than the possible minimal width and pitch achievable for individual probes of a probe array.

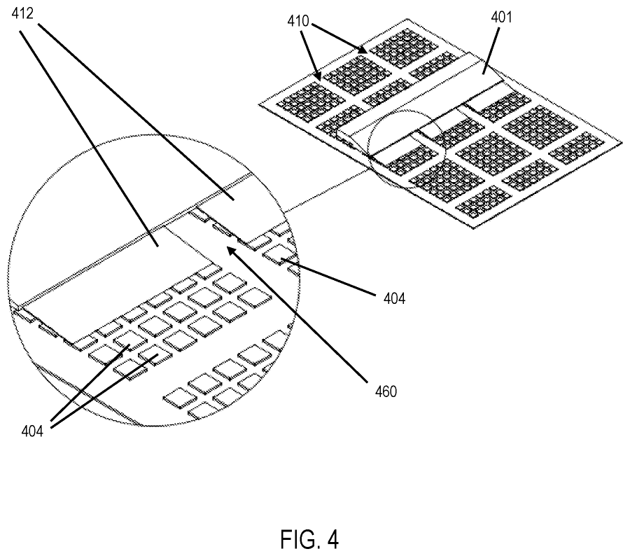

In yet another embodiment, a probe device could be similar to the conductive plane approach of FIG. 3 except that the plane is divided into different sections. FIG. 4 depicts such an example of a probe array structure 401 with separated conductive planes 412 having spaces 460 therebetween. The spaces (gaps) 460 between the planes 412 can correspond to gaps 410 in the individual devices 404 under test. The width of each plane 412 and the section(s) 460 between planes 412 can vary. Gaps 460 between planes 412 enable better matching of the DUT individual device pattern and less obstructive viewing. The separate planes allow for higher flexibility of the probe and is less affected by uneven surface flatness. The gaps 460 can mitigate effects of unexpected bumps and inconsistent texture on the surfaces of the DUT since the planes 412 can avoid possible bumps or other obstacles that might be disposed on the DUT in gaps 410, between devices 404, that positionally correspond to the gaps 460. A consistent probe structure allows for more consistent electrical contact and thus more repeatable readout from this excitation.

In some cases the electrical pads/contacts of an LED are covered by non-conductive layers so they provide no electrical access for the probe array. In this case, an AC high voltage source may be connected to the probe array and to a conductive surface that is placed under the DUT. In these situations, electrical excitation may be accomplished by imposing an AC voltage to the probe array, which is in contact with one side of the LED non-conductive layer, and a conductive plate which is in contact with the opposite side of the LED. The probe array and the conductive plate form a capacitor which can store and release charges under AC power. The AC voltage drives the recombination of electrons and holes inside the LED, i.e. current, which causes the LEDs to emit light. Conventional approaches using a capacitive excitation mechanism utilize only a single probe. In accordance with aspects described herein, approaches can excite multiple samples simultaneously by way of a probe array, and a soft probe enables exciting the LEDs without damaging the nonconductive layer around the LED. Thus, capacitive-driven testing in accordance with aspects described herein can utilize a flexible probe (instead of, say, a needle or conventional probe card, and can drive simultaneous testing of a plurality of devices). It is noted that the particular parameters of the capacitive excitation (such as voltage and frequency) could depend on the design of the sample itself (for instance characteristics like area of the contact pads, thickness of the non-conductive layer, structure of the sample, and/or the probe card itself, as examples).

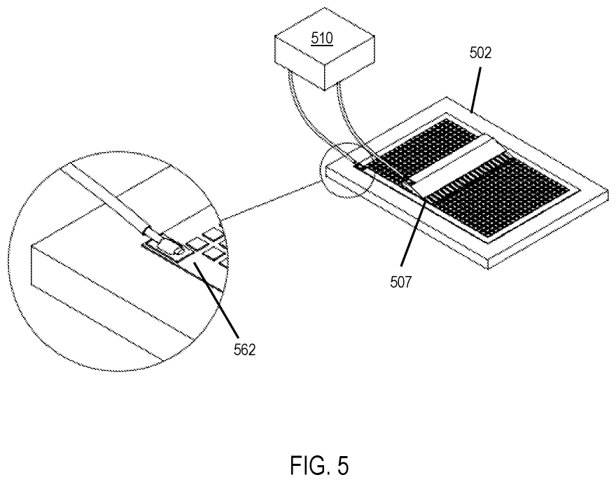

FIG. 5 depicts a schematic drawing of electrical excitation of a DUT 502 using a probe array 507 which is connected to one of the poles of a current/voltage supplying device 510, and the common ground 562 of the DUT is also connected to the current/voltage supplying device 510. This configuration is applicable for both-contact and contactless types of DUT testing.

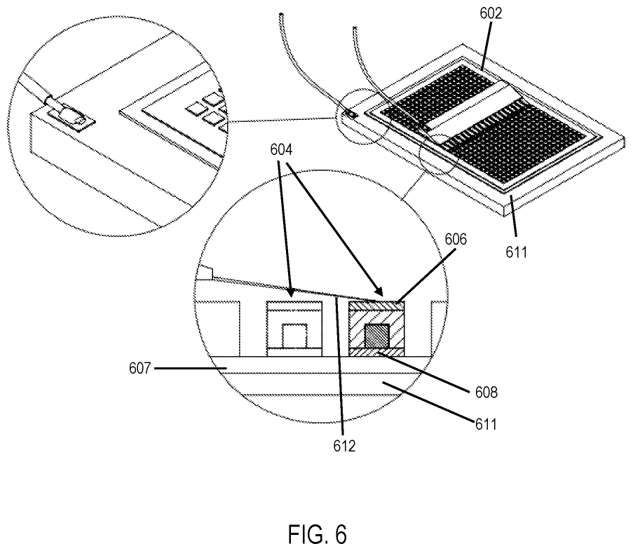

In general, FIG. 5 depicts a possibility for contact and contactless electrical excitation. FIG. 6 depicts an example schematic drawing of contactless (non-contact) electrical excitation of a DUT 602 having individual devices 604, and using a probe array of probes 612 which is connected to the pole of the current/voltage supplying device (as in FIG. 5) and a conductive plate 611 placed under the DUT 602 and non-conductive substrate 607, the DUT 602 being connected to another pole of the current/voltage supplying device. In this case, the accessibility/inaccessibility of the contact pads defines which one of the methods (contact/contactless) is used, as in this example 606 is a conductive pad and 608 is a non-accessible conductive pad. Thus, applying alternating voltage via the probe or the conductive pad can form a capacitor that drives excitation of the LED therebetween.

In some embodiments, the conductive plate can be transparent to enable the monitoring and detection of signals produced by the DUT (e.g., each individual device of the DUT) from below the DUT.

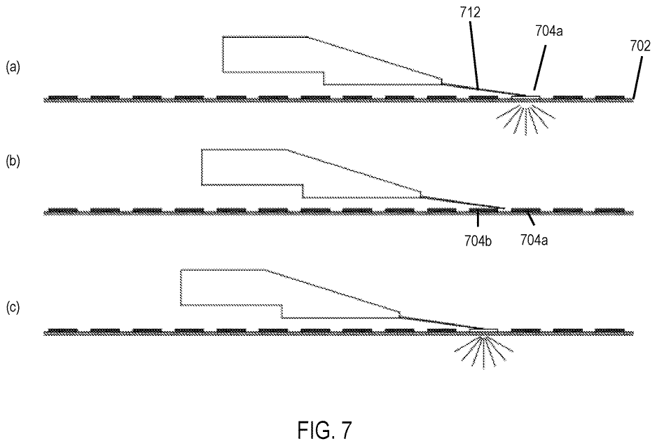

FIG. 7 depicts a schematic drawing of an optoelectronic device under test 702, in the case when the signals are detected from the bottom (underside of the DUT 702).

In cases of an optoelectronic device under test, for instance a microLED-based display, the microLEDs of the DUT emit light as a result of, for example, electroluminescence, and this emitted light is measured for each microLED.

A respective measurement of light emitted from each microLED may be obtained as an indication of the individual performance of each such microLED. Accurate measurement can be challenging if the probe array obstructs the optical device(s) that measure the emitted light. When probe contact points are on a same side of the test sample (DUT 702) as the individual devices under test (the microLEDs 704 in FIG. 7), then the probe tips to make contact at the contact points may be constructed with the appropriate geometry so that the emitted light from the devices under test is either not obscured or is essentially unperturbed.

The optical observation of the emission signals or other responses by the DUT in response to excitement thereof can be made from above, from below, and/or from an opposite side of the excitation, as examples. In some embodiments, a flat transparent surface, such as one on which the probe array is placed or coupled, is used for mechanical support and strength or other purposes, and also allows emitted light to pass therethrough for detection. It can also allow for excitation using the tool that could be driven by illumination of the wafer or device structure through the transparent surface and then measurement of a photovoltage or photocurrent generated in response. This may be the approach taken in solar array testing, for instance, where a voltage is generated with light or other solar excitation.

Referring still to FIG. 7, probe 712 drives excitation of devices 704 as the probe is drawn over/across the DUT 702, for instance to scan it, either by way of moving the probe (from right to left in this example), moving the DUT 702 (left to right in this example), or a combination of the two. As the probe and DUT are moved relative to each other, probe 712 can maintain continuous physical contact with the DUT, or the probe can come into contact with a sample 704, then out of contact with that sample, the into contact with a next sample 704. In FIG. 7 at (a), probe 712 is in contact with LED 704a (and/or a contact pad associated with 704a), to drive excitation of 704a and emission of light therefrom, which can be measured by an optical detector (as one example) from below DUT 702. It is noted that probe 712 could be drawn in a continuous motion across the contact of 704a, which causes 704a to illuminate for an amount of time. As the probe is drawn across the contact of 704a, the probe comes out of contact therewith as shown (b). The extreme end of probe 712 is shown in a space between 704a and a next sample 704b. The probe 712 can be drawn further so that, at (c), the probe end is in contact with LED 704b (and/or a contact pad associated with 704a), to drive excitation of 704b and emission of light therefrom, which can be measured as discussed above. This can repeat to test the samples of an entire row of samples. Meanwhile, the movement of the probe relative to the DUT could be continuous and consistent in terms of speed, if desired. In some embodiments, the height of the probe structure/housing above the DUT 702 is maintained at a constant height, and flexibility of the probe facilitates the dragging/sweeping of the end of the probe across the DUT, including individual samples thereof.

An example excitation and detection method is as follows:
The probe array is lowered toward the DUT until the probes reach physical and electrical contact with a matching line of pads/contacts on the DUT associated with a first plurality of samples;
In some examples where the DUT incorporates LED devices as the plurality of samples, they emit light as a results of excitation by the probes;
While the probe array is in contact with the DUT, relative and continuous movement as between the probe array and the DUT (in the horizontal direction for instance, and without the need to move in the vertical direction) is performed and the probe array reaches and comes into contact with a next plurality of matching pads/contacts;
In examples, a trigger is synchronized with the continuous movement, the trigger being a trigger delivered every fixed amount of distance, which correlates to a next plurality of devices being excited, to an optical/electrical detection system to measure signals from/acquire images of the excited devices (e.g., LEDs), synchronized to their location. In other words, while the array of probes is exciting a plurality of LEDs, a trigger may be sent to a detection system to cause the detection system to detect signals from the plurality of LEDs. This detection could occur for some amount of time (or until the trigger is released). Meanwhile, the probes eventually cease to excite that plurality of LEDs (based on movement of the probes and/or DUT), and the detection system awaits a next trigger, for instance one that is sent to the detection system based on contact of the probes with a next plurality of LEDs to excite the next plurality of LEDs. In this manner, the detection of signals can be selectively and sequentially enabled/disabled to coincide with sequential excitation of sets of devices of the DUT.
Thus, when the probe array reaches the next set of contacts, they excite the next set of corresponding LEDs, which excitement is detected by the detection system.
There are numerous iterations of the above process for different DUT areas/individual devices of the DUT.

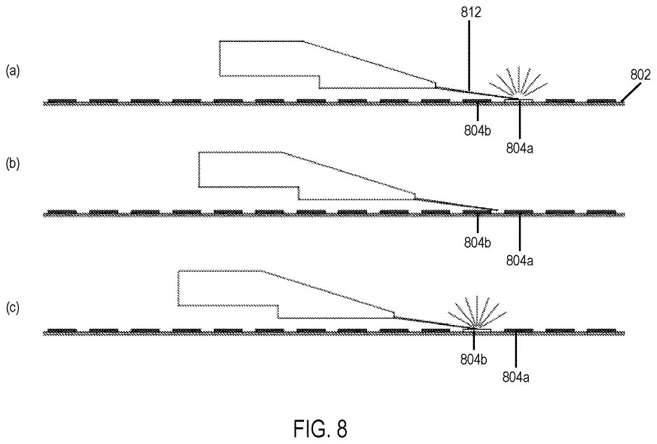

FIG. 8 depicts a schematic drawing of an optoelectronic device under test, in the case when the emission signals are detected from above the DUT. FIG. 8 is the same as FIG. except that emissions above the devices 804 are detected. As in the case of FIG. 7, there is relative movement between the probe 812 and the DUT 802, for instance a scanning of the probe 812 over the DUT 802 and/or scanning of the DUT 802 under the probe 812. In any case, the probe sequentially (i) comes into contact with a contact of a device 804a to excite that device 804a, (ii) comes out of contact with that contact of the device 804a, then (iii) comes into contact with a next contact of a next device 804b to excite that next device 804b. This can repeat one or more times for other devices under test.

Advantages of embodiments of devices/methods discussed herein are that they can enable much faster test speeds than conventional approaches Continuous movement with continuous physical contact can provide faster speed than the conventional way of testing using probe cards, which make contact between the probe and a contact pad, excitation of the sample, lifting the probe from the sample/DUT, moving the probe in the horizontal direction, stopping, approaching the next contact, and then exciting. For instance, acceleration and deacceleration in such a process could increase the time needed for inspection of a DUT.

Aspects also provide a probe array holder structure. The electrical communication between the probe array and the voltage/current supply may be fulfilled by a strong conductive spring structure. One end of the spring holds the probe array firmly and the other end is connected to electricity supply. The spring structure can ensure strong mechanical fixation of the probe arrays and a constant electrical communication between the probe array and the power supply. The spring, which could have a big accessible conductive surface area and strong mechanical properties, facilitates easier electrical connection.

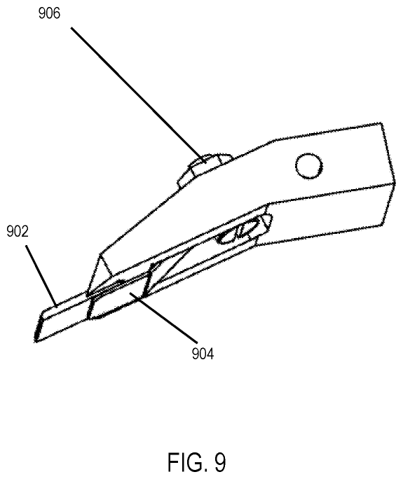

FIG. 9 depicts a schematic drawing of a probe support housing/structure which keeps the probe 902 in place using a spring structure 904. The spring structure 904 is conductive and can be in electrical communication with the probe 902 so that electrical signals can be passed between the probe 902 and another portion of the probe. In this manner, the spring structure can serve dual (at least) functions of retaining the probe 902 and also providing electrical conduction down to the probe 902 of the array. 906 is a device (such as a screw and nut) for retaining the spring structure 904 in place. The flexibility of the spring facilitates the easy replacement of the probe if desired. In some embodiments, automatic probe array replacement is facilitated; a relatively small footprint of the probe array and probe array holder (904) described above could enable a designated robot to remove the probe array holder and replace it automatically with a new probe array and probe array holder in case the probe array has been damaged.

Devices and related methods/processes have been described herein. For instance, processes for testing a sample array comprising individual samples are provided, and can use a test tool that includes test probes. A process may be executed, in one or more examples, by a processor or processing circuitry of one or more computers/computer systems, such as those described herein, for instance a computer system of, or in communication with, the test tool.

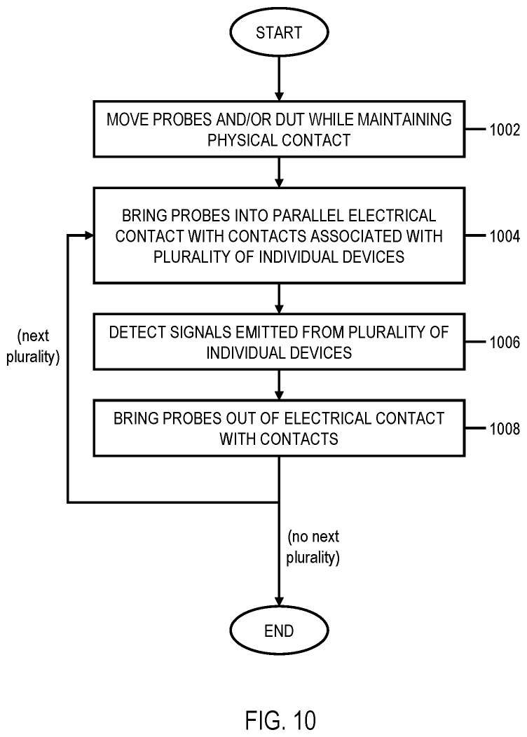

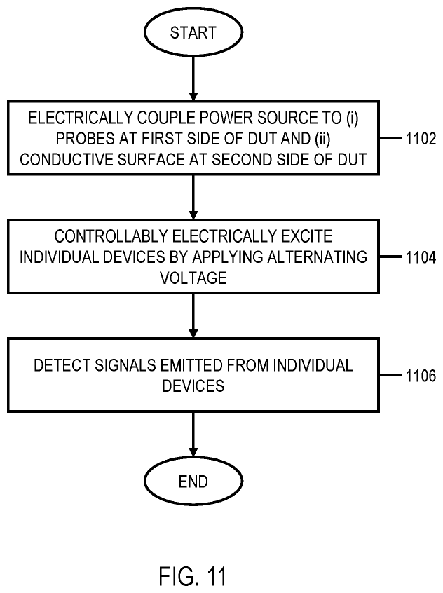

FIGS. 10 and 11 depict example methods for testing a collection of individual devices of a device under test (DUT). The example methods use a test tool that includes a plurality of probes. In examples, the individual devices are micro light-emitting diode (microLED) devices.

Referring initially to FIG. 10, the method sequentially tests multiple pluralities of individual devices of the collection of individual devices. This is done while the plurality of probes remain in physical contact with the DUT. The sequential testing includes moving (1002) at least one of (i) the plurality of probes or (ii) the DUT while maintaining physical contact between the plurality of probes and the DUT. The moving brings (1004) the plurality of probes into parallel electrical contact with a set of contacts associated with the plurality of individual devices to drive parallel electrical excitation of the plurality of individual devices. The method detects (1006) signals emitted from the plurality of individual devices based on the electrical excitation thereof, and the moving then brings (1008) the plurality of probes out of electrical contact with the set of contacts associated with the plurality of individual devices.

Continued movement of the probes and/or DUT can cause this process to repeat for a next plurality of individual devices, where parallel electrical contact is made to excite the next plurality of individual devices and the signals emitted therefrom are detected so that the process detects signals emitted from each plurality of individual devices of the multiple pluralities of individual devices based on the electrical excitation thereof. The repeated excitation and detection while the probes contact the DUT and one or both are moved can repeat one or more times until there is no next plurality of individual devices. This might involve reaching then end of a ‘sweep’ of the DUT, for instance, to test a corresponding number of rows of devices. Then, in some embodiments, the probes and/or DUT could be reset to a different position and the sequential testing of FIG. 10 could repeat for a next multiple pluralities of individual devices, for example.

In embodiments, each probe of the plurality of probes includes a flexible probe end that flexes on physical contact with the DUT.

In embodiments, the moving can move the plurality of probes over a surface of the DUT that has a variation in flatness which corresponds to the collection of individual devices. The plurality of probes can flex and maintain physical contact with the DUT while moving over the collection of individual devices.

In embodiments, the moving moves the plurality of probes across the DUT with a continuous movement and consistent speed.

The driving of the parallel excitation can impose a voltage or current, via the plurality of probes, to a set of contacts into which the plurality of probes is in contact to drive the parallel electrical excitation of the plurality of individual devices associated with that set of contacts.

Each probe of the plurality probes can optionally include a respective individual electrical channel to selectively excite a respective individual device of the plurality individual devices. Thus, a first individual electrical channel of a first probe of the plurality of probes could provide a voltage or current level that is different from a voltage or current level provided by a second individual electrical channel of a second probe of the plurality of probes, for instance.

In some embodiments, a probe of the plurality of probes is a conductive plane that, for each plurality of individual devices of the multiple pluralities of individual devices, comes into simultaneous electrical contact with two or more contacts of the set of contacts associated with the plurality of individual devices, and drives parallel electrical excitation of two or more individual devices of the plurality of individual devices associated with the two or more contacts. The plurality of probes could include a collection of such conductive planes, where each such plane excites a corresponding one or more devices for each successive plurality of individual devices.

In embodiments, the method can also synchronizes, with the moving, a trigger to a detection system that performs the detecting. The synchronizing can selectively and sequentially enable and disable detection of the signals to coincide with sequential excitation of the multiple pluralities of individual devices. Thus, the synchronizing can be used to control the detection system to detect emission signals when desired, for instance upon each successive excitation of each successive plurality of devices. In between the excitations, the detection by the system could be disabled, for instance.

FIG. 11 depicts another example method for testing a collection of individual devices of a DUT using a test tool having a plurality of probes. The method electrically couples (1102) a power source to (i) the plurality of probes positioned at a first side of the DUT and (ii) a conductive surface positioned at a second side of the DUT. In embodiments non-conductive material is disposed between (i) at least one of the conductive surface or the plurality of probes and (ii) respective electrical contacts associated with the plurality of individual devices. Example such material is layer(s) of non-conductive material. The method then controllably electrically excites (1104) a plurality of individual devices, of the collection of individual devices, by applying an alternating voltage to the plurality of probes relative to the conductive surface, and detects (1106) signals emitted from the plurality of individual devices based on the electrical excitation thereof.

In embodiments, and similar to that of method 10, this could be repeated for multiple pluralities of individual devices. Thus, in embodiments, the plurality of individual devices is a first plurality of the individual devices of the collection of individual devices and the plurality of probes electrically excite the first plurality of individual devices, and the method further includes (a) moving at least one of the plurality of probes or the DUT, where the moving electrically excites a next plurality of individual devices of the collection of individual devices, (b) detecting signals emitted from the next plurality of individual devices based on the electrical excitation thereof, and (c) repeating, one or more times, the moving and the detecting for a respective one or more additional plurality of individual devices.

In embodiments, the process of FIG. 11 effects capacitance-based testing of the individual devices. Thus, the testing could be accomplished with or without physical contact between the probes and the DUT or individual devices thereof. In a specific embodiment implementing sequential testing, the plurality of probes is in physical contact with the DUT, and the method further includes (a) moving at least one of the plurality of probes or the DUT while maintaining the physical contact between the plurality of probes and the DUT, where the moving electrically excites a next plurality of individual devices of the collection of individual devices, (b) detecting signals emitted from the next plurality of individual devices based on the electrical excitation thereof, and (c) repeating, one or more times, the moving and the detecting for each of one or more additional plurality of individual devices.

In embodiments, the conductive surface is transparent and the detecting is performed from the second side of the DUT based on the signals passing through the transparent conductive surface.

In embodiments, the DUT includes a non-conductive layer over the individual devices, and the plurality of probes include flexible probe ends that flex on physical contact with the non-conductive layer of the DUT.

In some examples, methods or aspects thereof may be performed by one or more computer systems, for examples computer system(s) that control a device/tool comprising an array of probes. The control can control movement of the tool, the DUT, and/or components of each, for instance. The computer system(s) could be incorporated with/provided as part of the tool or could communicate with the tool over one or more communications links, which may be any wired or wireless communication links configured for digital/data communications. In some examples, the computer system(s) may be remote from the tool. Thus, processes described herein may be performed singly or collectively by one or more computer systems. A computer system may also be referred to as a data processing device/system, computing device/system/node, or simply a computer. The computer system may be based on one or more of various system architectures and/or instruction set architectures, such as those offered by Intel Corporation (Santa Clara, California, USA) or ARM Holdings plc (Cambridge, England, United Kingdom), as examples.

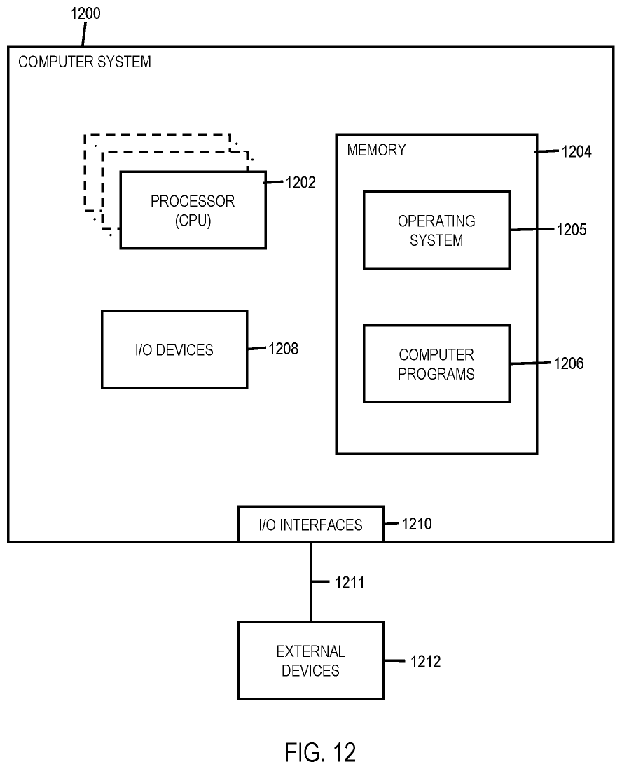

FIG. 12 shows a computer system 1200 in communication with external device(s) 1212. Computer system 1200 includes one or more processor(s) 1202, for instance central processing unit(s) (CPUs). A processor can include functional components used in the execution of instructions, such as functional components to fetch program instructions from locations such as cache or main memory, decode program instructions, and execute program instructions, access memory for instruction execution, and write results of the executed instructions. A processor 1202 can also include register(s) to be used by one or more of the functional components. Computer system 1200 also includes memory 1204, input/output (I/O) devices 1208, and I/O interfaces 1210, which may be coupled to processor(s) 1202 and each other via one or more buses and/or other connections. Bus connections represent one or more of any of several types of bus structures, including a memory bus or memory controller, a peripheral bus, an accelerated graphics port, and a processor or local bus using any of a variety of bus architectures. By way of example, and not limitation, such architectures include the Industry Standard Architecture (ISA), the Micro Channel Architecture (MCA), the Enhanced ISA (EISA), the Video Electronics Standards Association (VESA) local bus, and the Peripheral Component Interconnect (PCI).

Memory 1204 can be or include main or system memory (e.g. Random Access Memory) used in the execution of program instructions, storage device(s) such as hard drive(s), flash media, or optical media as examples, and/or cache memory, as examples. Memory 1204 can include, for instance, a cache, such as a shared cache, which may be coupled to local caches (examples include L1 cache, L2 cache, etc.) of processor(s) 1202. Additionally, memory 1204 may be or include at least one computer program product having a set (e.g., at least one) of program modules, instructions, code or the like that is/are configured to carry out functions of embodiments described herein when executed by one or more processors.

Memory 1204 can store an operating system 1205 and other computer programs 1206, such as one or more computer programs/applications that execute to perform aspects described herein. Specifically, programs/applications can include computer readable program instructions that may be configured to carry out functions of embodiments of aspects described herein.

Examples of I/O devices 1208 include but are not limited to microphones, speakers, Global Positioning System (GPS) devices, cameras, lights, accelerometers, gyroscopes, magnetometers, sensor devices configured to sense light, proximity, heart rate, body and/or ambient temperature, blood pressure, and/or skin resistance, and activity monitors. An I/O device may be incorporated into the computer system as shown, though in some embodiments an I/O device may be regarded as an external device (1212) coupled to the computer system through one or more I/O interfaces 1210.

Computer system 1200 may communicate with one or more external devices 1212 via one or more I/O interfaces 1210. Example external devices include a keyboard, a pointing device, a display, and/or any other devices that enable a user to interact with computer system 1200. Other example external devices include any device that enables computer system 1200 to communicate with one or more other computing systems or peripheral devices such as a printer. A network interface/adapter is an example I/O interface that enables computer system 1200 to communicate with one or more networks, such as a local area network (LAN), a general wide area network (WAN), and/or a public network (e.g., the Internet), providing communication with other computing devices or systems, storage devices, or the like. Ethernet-based (such as Wi-Fi) interfaces and Bluetooth® adapters are just examples of the currently available types of network adapters used in computer systems (BLUETOOTH is a registered trademark of Bluetooth SIG, Inc., Kirkland, Washington, U.S.A.).

The communication between I/O interfaces 1210 and external devices 1212 can occur across wired and/or wireless communications link(s) 1211, such as Ethernet-based wired or wireless connections. Example wireless connections include cellular, Wi-Fi, Bluetooth®, proximity-based, near-field, or other types of wireless connections. More generally, communications link(s) 1211 may be any appropriate wireless and/or wired communication link(s) for communicating data.

Particular external device(s) 1212 may include one or more data storage devices, which may store one or more programs, one or more computer readable program instructions, and/or data, etc. Computer system 1200 may include and/or be coupled to and in communication with (e.g. as an external device of the computer system) removable/non-removable, volatile/non-volatile computer system storage media. For example, it may include and/or be coupled to a non-removable, non-volatile magnetic media (typically called a “hard drive”), a magnetic disk drive for reading from and writing to a removable, non-volatile magnetic disk (e.g., a “floppy disk”), and/or an optical disk drive for reading from or writing to a removable, non-volatile optical disk, such as a CD-ROM, DVD-ROM or other optical media.

Computer system 1200 may be operational with numerous other general purpose or special purpose computing system environments or configurations. Computer system 1200 may take any of various forms, well-known examples of which include, but are not limited to, personal computer (PC) system(s), server computer system(s), such as messaging server(s), thin client(s), thick client(s), workstation(s), laptop(s), handheld device(s), mobile device(s)/computer(s) such as smartphone(s), tablet(s), and wearable device(s), multiprocessor system(s), microprocessor-based system(s), telephony device(s), network appliance(s) (such as edge appliance(s)), virtualization device(s), storage controller(s), set top box(es), programmable consumer electronic(s), network PC(s), minicomputer system(s), mainframe computer system(s), and distributed cloud computing environment(s) that include any of the above systems or devices, and the like.

Aspects of the present invention may be a system, a method, and/or a computer program product, any of which may be configured to perform or facilitate aspects described herein. In some embodiments, aspects of the present invention may take the form of a computer program product, which may be embodied as computer readable medium(s). A computer readable medium may be a tangible storage device/medium having computer readable program code/instructions stored thereon. Example computer readable medium(s) include, but are not limited to, electronic, magnetic, optical, or semiconductor storage devices or systems, or any combination of the foregoing. Example embodiments of a computer readable medium include a hard drive or other mass-storage device, an electrical connection having wires, random access memory (RAM), read-only memory (ROM), erasable-programmable read-only memory such as EPROM or flash memory, an optical fiber, a portable computer disk/diskette, such as a compact disc read-only memory (CD-ROM) or Digital Versatile Disc (DVD), an optical storage device, a magnetic storage device, or any combination of the foregoing. The computer readable medium may be readable by a processor, processing unit, or the like, to obtain data (e.g. instructions) from the medium for execution. In a particular example, a computer program product is or includes one or more computer readable media that includes/stores computer readable program code to provide and facilitate one or more aspects described herein.

As noted, program instruction contained or stored in/on a computer readable medium can be obtained and executed by any of various suitable components such as a processor of a computer system to cause the computer system to behave and function in a particular manner. Such program instructions for carrying out operations to perform, achieve, or facilitate aspects described herein may be written in, or compiled from code written in, any desired programming language. In some embodiments, such programming language includes object-oriented and/or procedural programming languages such as C, C++, C #, Java, etc.

Program code can include one or more program instructions obtained for execution by one or more processors. Computer program instructions may be provided to one or more processors of, e.g., one or more computer systems, to produce a machine, such that the program instructions, when executed by the one or more processors, perform, achieve, or facilitate aspects of the present invention, such as actions or functions described in flowcharts and/or block diagrams described herein. Thus, each block, or combinations of blocks, of the flowchart illustrations and/or block diagrams depicted and described herein can be implemented, in some embodiments, by computer program instructions.

Although various examples are provided, variations are possible without departing from a spirit of the claimed aspects.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising”, when used in this specification, specify the presence of stated features, integers, steps, operations, elements, and/or components, but do not preclude the presence or addition of one or more other features, integers, steps, operations, elements, components and/or groups thereof.

The corresponding structures, materials, acts, and equivalents of all means or step plus function elements in the claims below, if any, are intended to include any structure, material, or act for performing the function in combination with other claimed elements as specifically claimed. The description of one or more embodiments has been presented for purposes of illustration and description, but is not intended to be exhaustive or limited to in the form disclosed. Many modifications and variations will be apparent to those of ordinary skill in the art. The embodiment was chosen and described in order to best explain various aspects and the practical application, and to enable others of ordinary skill in the art to understand various embodiments with various modifications as are suited to the particular use contemplated.

What is claimed is:

1. A method for testing a collection of individual devices of a device under test (DUT), the method using a test tool comprising a plurality of probes, the method comprising:
sequentially testing multiple pluralities of individual devices, of the collection of individual devices, while the plurality of probes remains in physical contact with the DUT, the sequentially testing comprising:
moving at least one of the plurality of probes or the DUT while maintaining physical contact between the plurality of probes and the DUT, wherein the moving brings, for each successive plurality of the multiple pluralities of individual devices, the plurality of probes (i) into parallel electrical contact with a set of contacts associated with the plurality of individual devices to drive parallel electrical excitation of the plurality of individual devices, then (ii) out of electrical contact with the set of contacts associated with the plurality of individual devices; and
detecting signals emitted from each plurality of individual devices of the multiple pluralities of individual devices based on the electrical excitation thereof.

2. The method of claim 1, wherein each probe of the plurality of probes comprises a flexible probe end that flexes on physical contact with the DUT. The method of claim 2, wherein the moving moves the plurality of probes over a surface of the DUT having variation in flatness corresponding to the collection of individual devices, wherein the plurality of probes flex and maintain physical contact with the DUT while moving over the collection of individual devices.

4. The method of claim 1, wherein the driving imposes a voltage or current, via the plurality of probes, to the set of contacts into which the plurality of probes is in contact to drive the parallel electrical excitation of the plurality of individual devices associated with the set of contacts.

5. The method of claim 4, wherein each probe of the plurality probes comprises a respective individual electrical channel to selectively excite a respective individual device of the plurality of individual devices.

6. The method of claim 5, wherein a first individual electrical channel of a first probe of the plurality of probes provides a voltage or current level that is different from a voltage or current level provided by a second individual electrical channel of a second probe of the plurality of probes.

7. The method of claim 1, wherein a probe of the plurality of probes is a conductive plane that, for each plurality of individual devices of the multiple pluralities of individual devices, comes into simultaneous electrical contact with two or more contacts of the set of contacts associated with the plurality of individual devices, and drives parallel electrical excitation of two or more individual devices of the plurality of individual devices associated with the two or more contacts.

8. The method of claim 1, further comprising synchronizing, with the moving, a trigger to a detection system performing the detecting, the synchronizing selectively and sequentially enabling and disabling detection of the signals to coincide with sequential excitation of the multiple pluralities of individual devices.

9. The method of claim 1, wherein the moving moves the plurality of probes across the DUT with a continuous movement and consistent speed.

10. The method of claim 1, wherein the individual devices are micro light-emitting diode (microLED) devices.

11. A method for testing a collection of individual devices of a device under test (DUT), the method using a test tool comprising a plurality of probes, the method comprising:
electrically coupling a power source to (i) the plurality of probes positioned at a first side of the DUT and (ii) a conductive surface positioned at a second side of the DUT;
controllably electrically exciting a plurality of individual devices, of the collection of individual devices, by applying an alternating voltage to the plurality of probes relative to the conductive surface, wherein non-conductive material is disposed between (i) at least one of the conductive surface or the plurality of probes and (ii) respective electrical contacts associated with the plurality of individual devices; and
detecting signals emitted from the plurality of individual devices based on the electrical excitation thereof.

12. The method of claim 11, wherein the plurality of individual devices is a first plurality of the individual devices of the collection of individual devices and the plurality of probes electrically excite the first plurality of individual devices, and wherein the method further comprises:
moving at least one of the plurality of probes or the DUT, wherein the moving electrically excites a next plurality of individual devices of the collection of individual devices;
detecting signals emitted from the next plurality of individual devices based on the electrical excitation thereof; and
repeating, one or more times, the moving and the detecting for a respective one or more additional plurality of individual devices.

13. The method of claim 11, wherein the plurality of individual devices is a first plurality of the individual devices of the collection of individual devices, wherein the plurality of probes is in physical contact with the DUT, and wherein the method further comprises:
moving at least one of the plurality of probes or the DUT while maintaining the physical contact between the plurality of probes and the DUT, wherein the moving electrically excites a next plurality of individual devices of the collection of individual devices;
detecting signals emitted from the next plurality of individual devices based on the electrical excitation thereof; and
repeating, one or more times, the moving and the detecting for each of one or more additional plurality of individual devices.

14. The method of claim 11, wherein the conductive surface is transparent and wherein the detecting is performed from the second side of the DUT based on the signals passing through the transparent conductive surface.

15. The method of claim 11, wherein the DUT comprises a non-conductive layer over the individual devices, wherein the plurality of probes comprises flexible probe ends that flex on physical contact with the non-conductive layer of the DUT.
